(19) United States
(12) Patent Application Publication
(10) Pub. No.: US 2026/0293668 A1
(43) Pub. Date: Sep. 24, 2026

(54) CIRCUIT DEVICE WITH EMBEDDED HEAT SINK

(71) Applicant: TEXAS INSTRUMENTS INCORPORATED, DALLAS, TX (US)

(72) Inventors: Jaimal WILLIAMSON, McKinney, TX (US); Hiep NGUYEN, CEDAR HILL, TX (US); Karthekeyan SRIDHAR, DALLAS, TX (US); Yutaka SUZUKI, ALLEN, TX (US)

(21) Appl. No.: 19/083,645

(22) Filed: Mar. 19, 2025

(51) Int. Cl. H10W 40/22; H10P 50/24; H10P 50/64; H10P 52/00; H10W 40/25; H10W 70/02; H10W 74/10; H10W 74/40; H10W 72/00; H10W 72/30; H10W 90/00

(52) U.S. Cl. CPC H10W 40/22; H10P 50/242; H10P 50/642; H10P 52/00; H10W 40/255; H10W 70/023; H10W 74/137; H10W 74/40; H10W 72/073; H10W 72/342; H10W 90/736

(57) ABSTRACT

One example includes a method for fabricating a circuit device. The method includes removing a portion of semiconductor material from a surface of a semiconductor die to form a recess with respect to the surface. The recess includes at least one interior surface. The method also includes providing a metallization layer on the semiconductor material of the at least one interior surface of the recess. The method further includes providing a metal material onto the metallization layer in the recess to at least partially fill the recess with the metal material to form an embedded heat sink in the semiconductor die.

### TECHNICAL FIELD

This description relates to electronic circuits, and more specifically to a circuit device with an embedded heat sink.

### BACKGROUND

Integrated circuits can include portions that require operation at higher power. Such portions can be concentrated in certain areas of the associated semiconductor die, which can result in spots on the semiconductor in which local heat can be excessive. Such excessive local heat in a semiconductor die can result in deleterious performance and/or damage in the associated circuit device. Withdrawing the heat from an integrated circuit can thus be desirable to improve the performance of the circuit and to prevent damage to the circuit and surrounding components. Integrated circuit chips can be cooled by passing a flow of cooling fluid through a cold plate in close proximity to remove heat from an integrated circuit. Air cooling integrated circuits in controlled climate environments can be employed to reduce the heat from the integrated circuit. Heat sinks can be coupled to the integrated circuit to remove heat.

### SUMMARY

One example includes a method for fabricating a circuit device. The method includes removing a portion of semiconductor material from a surface of a semiconductor die to form a recess with respect to the surface. The recess includes at least one interior surface. The method also includes providing a metallization layer on the semiconductor material of the at least one interior surface of the recess. The method further includes providing a metal material onto the metallization layer in the recess to at least partially fill the recess with the metal material to form an embedded heat sink in the semiconductor die.

Another example includes a circuit device. The device includes a semiconductor die formed from a semiconductor material and comprising a surface. A recess is formed in the surface, with the recess corresponding to an absence of the semiconductor material with respect to the surface. The device further includes an embedded heat sink formed in the semiconductor die, the embedded heat sink comprising a metal material formed in and at least partially filling the recess.

Another example includes a method for fabricating a circuit device. The method includes forming electrical contacts on a first surface of a semiconductor die. The semiconductor die includes a second surface opposite the first surface. The method also includes removing a portion of semiconductor material from the second surface of the semiconductor die to form a recess with respect to the second surface. The recess includes at least one interior surface. The method also includes providing a metallization layer on the semiconductor material of the at least one interior surface of the recess. The method further includes providing a metal material onto the metallization layer in the recess to at least partially fill the recess with the metal material to form an embedded heat sink in the semiconductor die.

### BRIEF DESCRIPTION OF THE DRAWINGS

FIG. 1 is an example block diagram of a circuit device.

FIG. 2 is an example diagram of a heat profile of a semiconductor die.

FIG. 3A is an example diagram of a circuit device.

FIG. 3B is another example diagram of a circuit device.

FIG. 4 is an example of a first step of fabricating a semiconductor wafer.

FIG. 5 is an example of a second step of fabricating a semiconductor wafer.

FIG. 6 is an example of a third step of fabricating a semiconductor wafer.

FIG. 7 is an example of a fourth step of fabricating a semiconductor wafer.

FIG. 8 is an example of a fifth step of fabricating a semiconductor wafer.

FIG. 9 is another example diagram of a surface of a semiconductor die.

FIG. 10 is an example of a first step of fabricating a semiconductor wafer.

FIG. 11 is an example of a second step of fabricating a semiconductor wafer.

FIG. 12 is an example of a third step of fabricating a semiconductor wafer.

FIG. 13 is an example of a fourth step of fabricating a semiconductor wafer.

FIG. 14 is an example of a method for providing loopback testing of a circuit device.

### DETAILED DESCRIPTION

This description relates to electronic circuits, and more specifically to a circuit device with an embedded heat sink. A circuit device described herein can correspond to any of a variety of circuit devices, such as any of a variety of flip-chip circuits. For example, the circuit device can correspond to a flip-chip chip-scale package (FCCSP) or a flip-chip ball-grid array (FCBGA). The circuit device can be fabricated to include an embedded heat sink that is formed by removing a portion of semiconductor material from a surface of a semiconductor die to form a recess in the surface. The embedded heat sink can thus be formed by at least partially filling the recess with a metal material.

As an example, the embedded heat sink can be formed over at least a portion of a hot spot associated with the semiconductor die. As described herein, the term “hot spot” refers to a local portion of the semiconductor die associated with a high power operating region of the associated circuit device, such that the high power operating region of the circuit device can result in an operating temperature that exceeds a desirable threshold. As a result, the embedded heat sink can be configured to dissipate heat from the hot spot to mitigate deleterious performance and/or damage to the associated circuit device.

As an example, the embedded heat sink can be formed to have a peripheral area that circumscribes the hot spot, such as to provide local heat dissipation from the hot spot. Because the embedded heat sink can be formed to circumscribe the hot spot, the location of the embedded heat sink can be asymmetrical with respect to at least one of orthogonal axes that bisect the surface of the semiconductor die. As another example, the circuit device can include a metal layer that is formed over the embedded heat sink and at least a portion of the remaining surface of the semiconductor die. For example, the metal layer can have peripheral edges that extend to and are aligned with peripheral edges of the semiconductor die. As yet another example, the embedded heat sink can be formed symmetrically with respect to both orthogonal axes that bisect the surface of the semiconductor die. In such an example, the embedded heat sink can have an area of an exposed surface that is greater than an area of the surface of the semiconductor die that surrounds the embedded heat sink. The embedded heat sink can thus also be configured to provide greater stability of the semiconductor die when fabricating an associated circuit device package by mitigating warping of the semiconductor die, thereby mitigating potential failures of the semiconductor die during testing that can result from high stress associated with the warping.

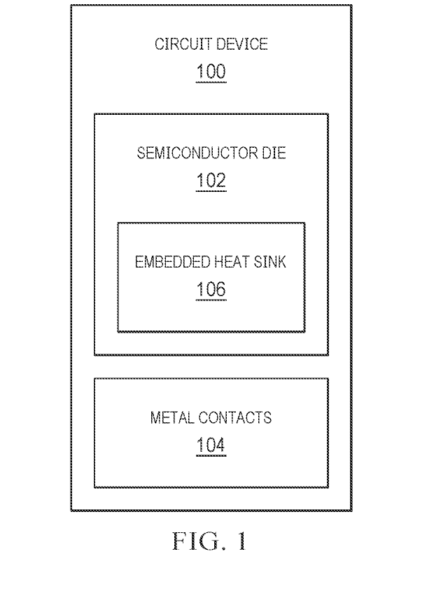

FIG. 1 is an example block diagram of a circuit device 100. The circuit device 100 can be fabricated as any of a variety of integrated circuits to implement any of a variety of circuit functions. As an example, the circuit device 100 can be implemented as a flip-chip chip-scale package (FCCSP), a flip-chip ball-grid array (FCBGA), or any of a variety of other flip-chip integrated circuits.

The circuit device 100 is demonstrated in the example of FIG. 1 as including a semiconductor die 102 and a set of metal contacts 104. The semiconductor die 102 includes an embedded heat sink 106. As an example, the metal contacts 104 can be formed on a first surface of the semiconductor die 102 and the embedded heat sink 106 can be formed on a second surface of the semiconductor die 102 opposite the first surface. The embedded heat sink 106 can be formed by removing a portion of semiconductor material from a surface of the semiconductor die 102 to form a recess in the surface of the semiconductor die 102. The embedded heat sink 106 can thus be formed by at least partially filling the recess with a metal material. For example, a metallization layer can be formed over one or more interior surfaces of the recess, such that the metal material can be provided over the metallization layer to form the embedded heat sink 106.

As an example, the embedded heat sink 106 can be formed over at least a portion of a hot spot associated with the semiconductor die. The hot spot can result from operation of a high power portion of the associated circuit in the semiconductor die 102, such as to form a region of the semiconductor die 102 that can operate at a temperature that increases beyond a desirable threshold. For example, sustained operation at the increased temperature can result in deleterious effects on and/or damage to the circuit device 100. Accordingly, the embedded heat sink 106 can mitigate the undesirable effects of the hot spot. For example, the embedded heat sink 106 can achieve a significant reduction in both theta-jc and theta-ja (e.g., between approximately 30% and approximately 35%) of the semiconductor die 102. As an example, the embedded heat sink 106 can be formed over at least a portion of the hot spot, such as having a peripheral area that circumscribes the hot spot.

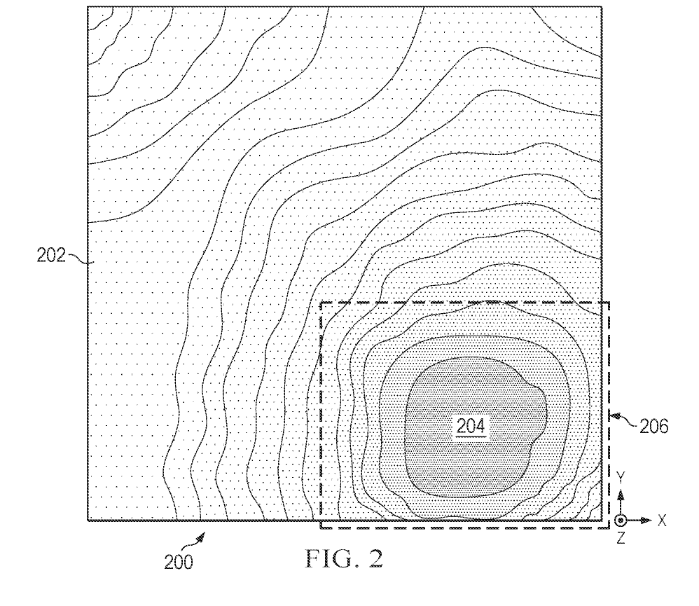

FIG. 2 is an example diagram 200 of a heat profile of a semiconductor die 202. The semiconductor die 202 can correspond to the semiconductor die 102 in the example of FIG. 1. The diagram 200 demonstrates a relative heat across the semiconductor die 202 based on relative shading, with darker shaded portions of the heat profile corresponding to relatively higher temperatures. The darkest portions of the heat profile can thus correspond to a hot spot 204 that exhibits temperatures that are greater than a desired threshold. Therefore, the semiconductor die 202 can be fabricated to include the embedded heat sink 106, such that the embedded heat sink 106 at least partially covers the hot spot 204. For example, the diagram 200 demonstrates an area 206 across the surface of the semiconductor die 202 that circumscribes the hot spot 204, such that the embedded heat sink 106 can be fabricated to have an area that is approximately equal to the area 206.

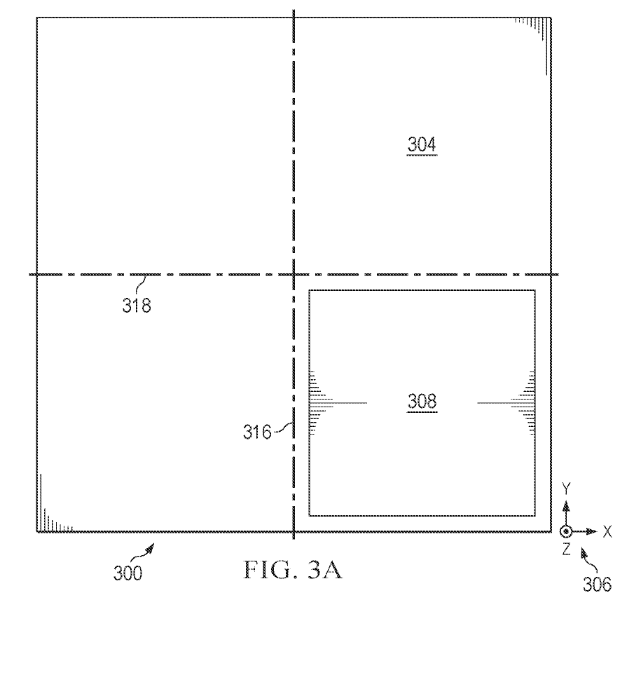

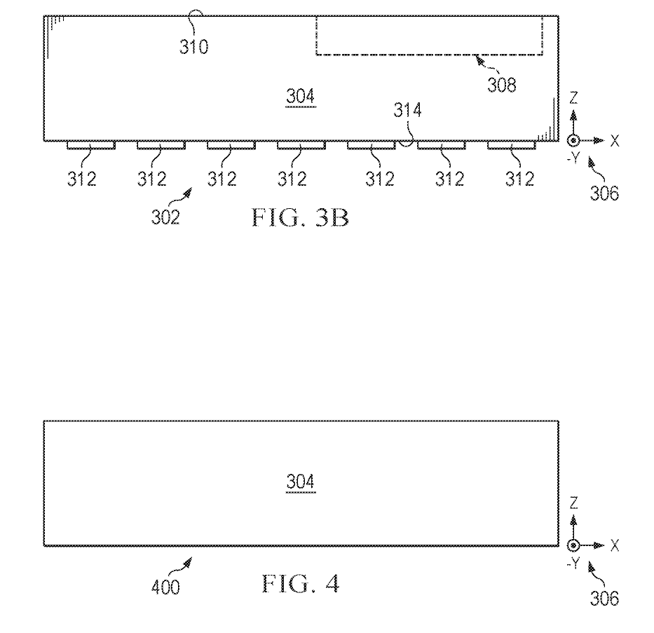

FIG. 3A is an example diagram 300 of a first view of a semiconductor die 304, and FIG. 3B is an example diagram 302 of a second view of the semiconductor die 304. The semiconductor die 304 can correspond to the semiconductor dies 102 and 202 in the respective examples of FIGS. 1 and 2. The diagram 300 demonstrates a plan view of the surface of the semiconductor die 304, while the diagram 302 demonstrates a side view, as provided by the Cartesian coordinate system 306. In the examples of FIGS. 3A and 3B, the semiconductor die 304 includes an embedded heat sink 308 formed in a first surface 310 of the semiconductor die 304, such that the exposed surface of the embedded heat sink 308 is approximately coplanar with the first surface 310 of the semiconductor die 304. In addition, in the example of FIG. 3B, electrical contacts 312 are formed on a second surface 314 of the semiconductor die 304, and thus on the surface opposite the embedded heat sink 308.

The embedded heat sink 308 can be formed over the hot spot 204, such that the embedded heat sink 308 has a peripheral area (e.g., area of an exposed surface of the embedded heat sink 308) that circumscribes the hot spot 204. As a result, the embedded heat sink 308 can dissipate heat that is generated at the hot spot 204, and can thereby mitigate the undesirable effects of the excessive temperatures of the hot spot 204. The location of the hot spot 204 can be arbitrary on the semiconductor die 304. Therefore, because the embedded heat sink 308 can be formed over (e.g., circumscribing) the arbitrarily located hot spot 204, the location of the embedded heat sink 308 can correspond to the arbitrary location of the hot spot 204. As a result, the embedded heat sink 308 is demonstrated as being asymmetrical with respect to at least one of two orthogonal axes, demonstrated as 316 and 318 in the example of FIG. 3A, that each bisect the surface of the semiconductor die 304. However, the embedded heat sink 308 can instead be formed symmetrical with respect to one or both of the orthogonal axes 316 and 318, as described in greater detail herein.

FIGS. 4-8 demonstrate steps for fabricating the circuit device 100 in the examples described herein. Therefore, like reference numbers are used in the examples of FIGS. 4-8 as provided in FIGS. 3A and 3B, and reference to FIG. 2 is to be made in the following examples of FIGS. 4-8.

FIG. 4 is an example of a first fabrication step 400. In the first fabrication step 400, the semiconductor die 304 is provided. The semiconductor die 304 can be formed during a fabrication process, for example, to fabricate an integrated circuit (not shown) therein. While the electrical contacts 312 are not demonstrated in the example of FIG. 4, the first fabrication step 400 can occur after fabrication of the electrical contacts 312. Alternatively, the electrical contacts 312 can be formed on the semiconductor die 304 after the embedded heat sink 308 is formed.

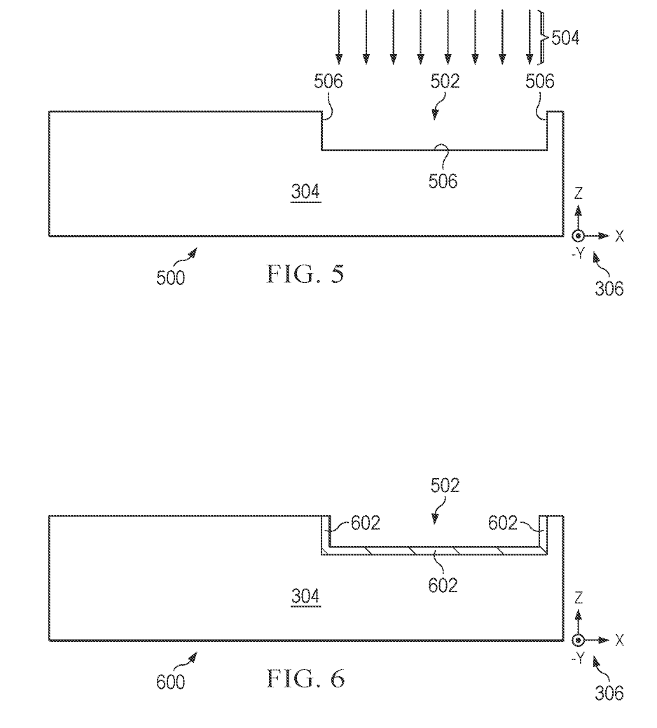

FIG. 5 is an example of a second fabrication step 500. In the second fabrication step 500, a portion of semiconductor material is removed from the semiconductor die 304 to form a recess 502. The removal process of the semiconductor material to form the recess 502 is demonstrated in the example of FIG. 5 at 504. The removal process 504 can occur in a variety of different ways, such as resulting from an etching process (e.g., chemical or plasma etching), a mechanical grinding process, or any of a variety of other ways to remove the semiconductor material to a sufficient depth. The depth of the recess 502 can be optimized to be sufficiently shallow so as to not interfere with fabricated circuit components of the integrated circuit within the semiconductor die 304 but sufficiently deep to optimize heat dissipation from the hot spot 204. The recess 502 is demonstrated as including interior surfaces 506. The interior surfaces 506 can be planar, curved, or have any of a variety of dimensions, such as based on the removal process 504 of the semiconductor material.

FIG. 6 is an example of a third fabrication step 600. In the third fabrication step 600, a metallization layer 602 is provided on at least one of the interior surfaces 506. The metallization layer 602 can be any of a variety of high thermal conductivity metal materials (e.g., copper or aluminum). The metallization layer 602 can be provided based on a sputtering process, a metallization process, or any of a variety of other processes to provide a thin metal seed layer to the interior surface(s) 506. While the example of FIG. 6 demonstrates that the metallization layer 602 is provided on all of the interior surface(s) 506, the metallization layer 602 can be provided on less than all or portions of one or more of the interior surfaces 506.

FIG. 7 is an example of a fourth fabrication step 700. In the fourth fabrication step 700, a metal material 702 is provided over the metallization layer 602 to at least partially fill the recess 502. Thus, the metal material 702 formed in the recess 502 (over the metallization layer 602) can correspond to the embedded heat sink 308. As an example, the metal material 702 can be any of a variety of high thermal conductivity metal materials (e.g., copper or aluminum), and may or may not be different from the material of the metallization layer 602.

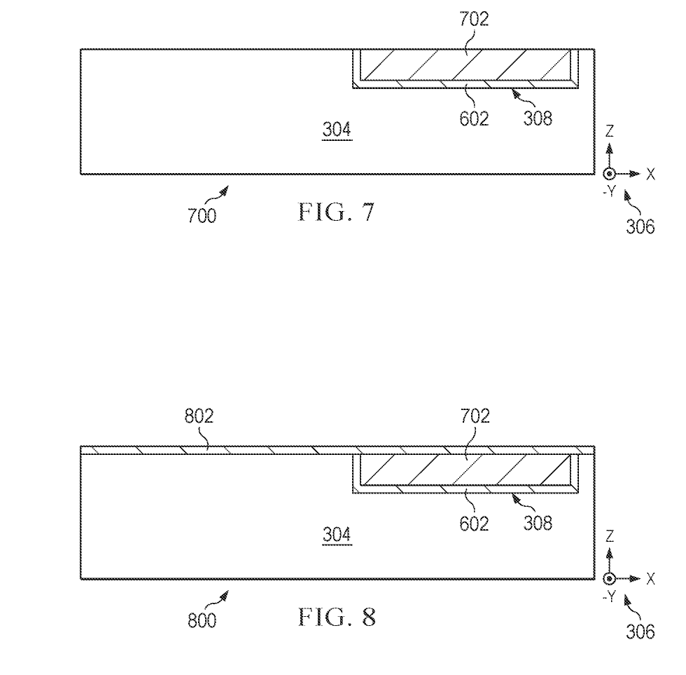

As an example, the process of fabricating the embedded heat sink 308 can be concluded after the fourth fabrication step 700. The electrical contacts 312 can be fabricated on the semiconductor die 304 after the fourth fabrication step 700 (e.g., if not prior to the first fabrication step 400). Thus, the embedded heat sink 308 can provide local thermal dissipation of a hot spot. As another example, an additional metal layer can be formed on the surface of the semiconductor die 304, as demonstrated in the example of FIG. 8.

FIG. 8 is an example of a fifth fabrication step 800. In the fifth fabrication step 800, a metal layer 802 is formed over the embedded heat sink 308 and over at least a remaining portion of the surface of the semiconductor die 304. As an example, the metal layer 802 can be any of a variety of high thermal conductivity metal materials (e.g., copper or aluminum), and may or may not be different from the material of the metallization layer 602 and/or the metal material 702 that forms the embedded heat sink 308. In the example of FIG. 8, the metal layer 802 is demonstrated as having a peripheral edge that is aligned with a peripheral edge of the semiconductor die 304. However, the area of the metal layer 802 can be more than the area of the surface of the semiconductor die 304, such as by extending over one or more edges of the semiconductor die 304, or less than the area of the surface of the semiconductor die 304, such as by not extending to the edge(s) of the semiconductor die 304. The metal layer 802 can provide, for example, additional heat dissipation capability by allowing the heat that dissipates from the hot spot via the embedded heat sink 308 to further spread out through the metal layer 802.

As described above, the embedded heat sink 308 is demonstrated as being asymmetrical with respect to at least one of the two orthogonal axes 316 and 318 in the example of FIG. 3A based on the arbitrary location of the hot spot and the local formation of the embedded heat sink 308 thereon. However, as also described above, the embedded heat sink can instead be formed symmetrical with respect to both of the orthogonal axes 316 and 318.

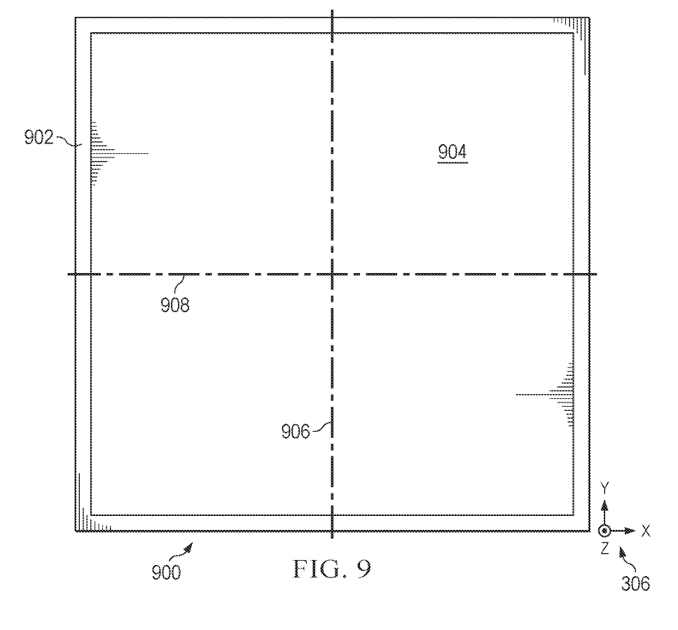

FIG. 9 is another example diagram 900 of a semiconductor die 902. The semiconductor die 902 can correspond to the semiconductor dies 102 and 202 in the respective examples of FIGS. 1 and 2. The diagram 900 demonstrates a plan view of the surface of the semiconductor die 902. In the example of FIG. 9, the semiconductor die 902 includes an embedded heat sink 904 formed on the first surface of the semiconductor die 902. Similar to as described in the example of FIG. 3B, electrical contacts (not shown) can be formed on an opposite surface of the semiconductor die 902 to provide for a flip-chip circuit design.

In the example of FIG. 9, the embedded heat sink 904 can be formed in a large portion of the surface of the semiconductor die 902. For example, the embedded heat sink 904 can have an exterior surface that has an area that is greater than an area of the surface of the semiconductor die 902 that surrounds the embedded heat sink 904. In the example of FIG. 9, unlike the example of FIG. 3A, the embedded heat sink 904 can be formed symmetrical with respect to both of the orthogonal axes 906 and 908 that each bisect the surface of the semiconductor die 902. While the hot spot 204 can be arbitrarily located on the semiconductor die 902, the embedded heat sink 904 can cover a sufficiently large area that the location of the hot spot 204 is largely irrelevant for purposes of heat dissipation capability of the embedded heat sink 904. Therefore, regardless of the location of the hot spot 204 beneath the embedded heat sink 904, the embedded heat sink 904 can dissipate the heat from the hot spot 204 to mitigate the deleterious effects and/or damage caused by the excessive heat at the hot spot 204.

In addition to providing thermal dissipation, the embedded heat sink 904 can provide structural stability of the semiconductor die 902, such as during testing of the semiconductor die 902. For example, the rigidity of the embedded heat sink 904 can provide for a significantly more uniform and damped loading applied on the exposed semiconductor die 902, such as during testing of the semiconductor die 902.

For example, subsequent to fabrication and assembly, the semiconductor die 902 can exhibit warpage that provides a convex shape of the semiconductor die 902. The convex shape resulting from the warpage of the semiconductor die 902 can generate high mechanical stress at the approximate center of the semiconductor die 902. The high stress can thus result in potential failures of the semiconductor die 902 during test insertion of the semiconductor die 902. For example, the potential failures can include die cracking, back-end of line (BEoL) cracking, substrate cracking, and/or other types of failures that can result in damage to or destruction of the semiconductor die 902.

However, by adding the embedded heat sink 904, the warpage on the semiconductor die 902 can be greatly mitigated, resulting in damping the stress load on the semiconductor die 902. Accordingly, the high stress that can cause the potential failures during test insertion of the semiconductor die 902 can be mitigated to mitigate the potential failures. As a result, the embedded heat sink 904 can provide both heat dissipation and mechanical support to improve package reliability during testing of the semiconductor die 902.

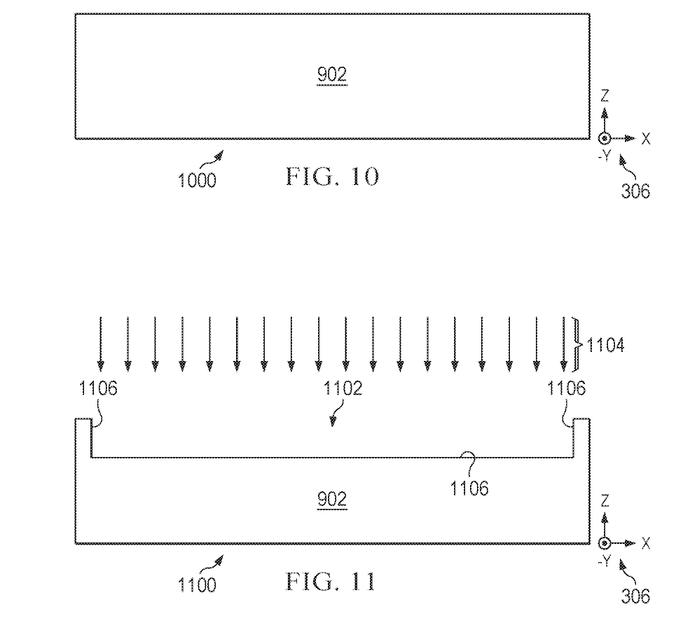

FIGS. 10-13 demonstrate another example of steps for fabricating the circuit device 100 in the examples described herein. Therefore, like reference numbers are used in the examples of FIGS. 10-13 as provided in FIG. 9, and reference to FIG. 9 is to be made in the following examples of FIGS. 10-13.

FIG. 10 is an example of a first fabrication step 1000. In the first fabrication step 1000, the semiconductor die 902 is provided. The semiconductor die 902 can be formed during a fabrication process, for example, to fabricate an integrated circuit (not shown) therein. While electrical contacts are not demonstrated in the example of FIG. 10, the first fabrication step 1000 can occur after fabrication of the electrical contacts. Alternatively, the electrical contacts can be formed on the semiconductor die 902 after the embedded heat sink 904 is formed.

FIG. 11 is an example of a second fabrication step 1100. In the second fabrication step 1100, a portion of semiconductor material is removed from the semiconductor die 902 to form a recess 1102. The removal process of the semiconductor material to form the recess 1102 is demonstrated in the example of FIG. 11 at 1104. The removal process 1104 can occur in a variety of different ways, such as resulting from an etching process (e.g., chemical or plasma etching), a mechanical grinding process, or any of a variety of other ways to remove the semiconductor material to a sufficient depth. The depth of the recess 1102 can be optimized to be sufficiently shallow so as to not interfere with fabricated circuit components of the integrated circuit within the semiconductor die 902 but sufficiently deep to optimize heat dissipation from the hot spot 204. The recess 1102 is demonstrated as including interior surfaces 1106. The interior surfaces 1106 can be planar, curved, or have any of a variety of dimensions, such as based on the removal process 1104 of the semiconductor material.

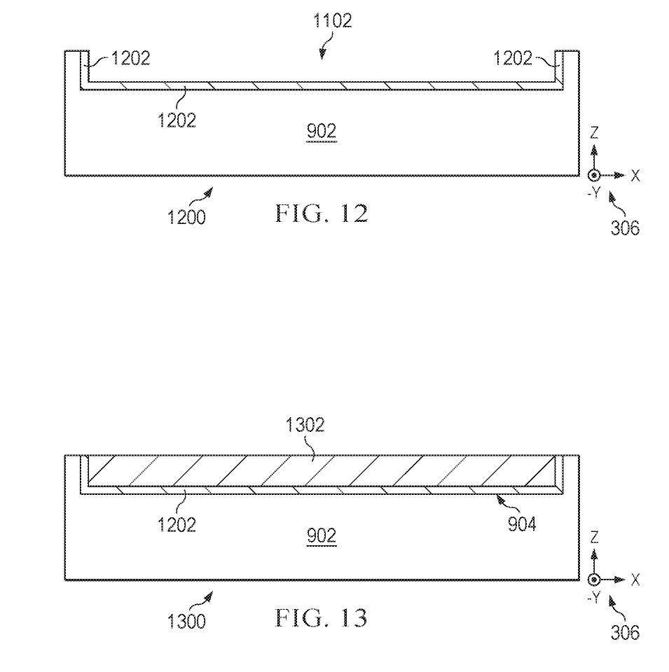

FIG. 12 is an example of a third fabrication step 1200. In the third fabrication step 1200, a metallization layer 1202 is provided on at least one of the interior surfaces 1106. The metallization layer 1202 can be any of a variety of high thermal conductivity metal materials (e.g., copper or aluminum). The metallization layer 1202 can be provided based on a sputtering process, a metallization process, or any of a variety of other processes to provide a thin metal seed layer to the interior surface(s) 1106. While the example of FIG. 12 demonstrates that the metallization layer 1202 is provided on all of the interior surface(s) 1106, the metallization layer 1202 can be provided on less than all or portions of one or more of the interior surfaces 1106.

FIG. 13 is an example of a fourth fabrication step 1300. In the fourth fabrication step 1300, a metal material 1302 is provided over the metallization layer 1202 to at least partially fill the recess 1102. Thus, the metal material 1302 formed in the recess 1102 (over the metallization layer 1202) can correspond to the embedded heat sink 904. As an example, the metal material 1302 can be any of a variety of high thermal conductivity metal materials (e.g., copper or aluminum), and may or may not be different from the material of the metallization layer 1202. Similar to as described above in the example of FIG. 8, the fabrication of the embedded heat sink 904 can include the additional step of adding a metal layer.

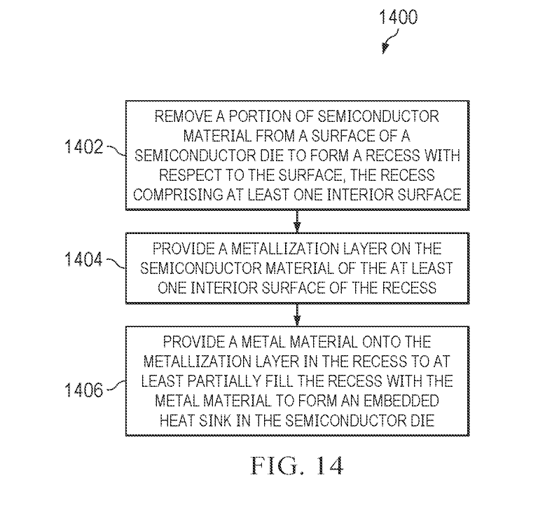

In view of the foregoing structural and functional features described above, methodologies in various aspects of the description will be better appreciated with reference to FIG. 14. The method of FIG. 14 is not limited by the illustrated order, as some aspects could, in the present description, occur in different orders and/or concurrently with other aspects from that shown and described herein. Moreover, not all illustrated features may be required to implement methodologies in an aspect of the present examples.

FIG. 14 is an example of a method 1400 for fabricating a circuit device (e.g., the circuit device 100). At 1402, a portion of semiconductor material is removed from a surface (e.g., the first surface 310) of a semiconductor die (e.g., the semiconductor die 102) to form a recess (e.g., the recess 502) with respect to the surface. The recess can include at least one interior surface (e.g., the interior surface(s) 506). At 1404, a metallization layer (e.g., the metallization layer 602) is provided on the semiconductor material of the at least one interior surface of the recess. At 1406, a metal material (e.g., the metal material 702) is provided onto the metallization layer in the recess to at least partially fill the recess with the metal material to form an embedded heat sink (e.g., the embedded heat sink 106) in the semiconductor die.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter or, if the parameter is zero, a reasonable range of values around zero.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A method for fabricating a circuit device, the method comprising:
removing a portion of semiconductor material from a surface of a semiconductor die to form a recess with respect to the surface, the recess comprising at least one interior surface;
providing a metallization layer on the semiconductor material of the at least one interior surface of the recess; and
providing a metal material onto the metallization layer in the recess to at least partially fill the recess with the metal material to form an embedded heat sink in the semiconductor die.

2. The method of claim 1, wherein removing the portion of the semiconductor material comprises removing the portion of the semiconductor material over at least a portion of a predetermined hot spot associated with the semiconductor die.

3. The method of claim 2, wherein removing the portion of the semiconductor material comprises removing the portion of the semiconductor material that circumscribes the predetermined hot spot associated with the semiconductor die.

4. The method of claim 1, wherein removing the portion of the semiconductor material comprises removing the portion of the semiconductor material that is asymmetrical with respect to at least one of two orthogonal axes that each bisect the surface of the semiconductor die.

5. The method of claim 1, further comprising providing a metal layer onto the surface of the semiconductor die to cover the embedded heat sink and at least a portion of the surface of the semiconductor die.

6. The method of claim 5, wherein providing the metal layer comprises providing the metal layer onto the surface of the semiconductor die to completely cover the surface of the semiconductor die, such that a periphery of the metal layer is aligned with a periphery of the surface of the semiconductor die.

7. The method of claim 1, wherein removing the portion of the semiconductor material comprises removing the portion of the semiconductor material that is symmetrical with respect to two orthogonal axes that each bisect the surface of the semiconductor die.

8. The method of claim 7, wherein removing the portion of the semiconductor material comprises removing the portion of the semiconductor material such that an area of an exposed surface of the embedded heat sink is greater than an area than a remaining portion of the surface of the semiconductor die.

9. The method of claim 1, wherein the surface of the semiconductor die is a first surface, the method further comprising forming electrical contacts on a second surface of the semiconductor die opposite the first surface.

10. A circuit device comprising:
a semiconductor die formed from a semiconductor material and comprising a surface, wherein a recess is formed in the surface, the recess corresponding to an absence of the semiconductor material with respect to the surface; and
an embedded heat sink formed in the semiconductor die, the embedded heat sink comprising a metal material formed in and at least partially filling the recess.

11. The device of claim 10, wherein the recess comprises at least one interior surface, wherein the embedded heat sink further comprises a metallization layer formed on the semiconductor material of the at least one interior surface of the recess, such that the metal material is formed on the metallization layer.

12. The device of claim 10, wherein the recess is formed over at least a portion that circumscribes a predetermined hot spot associated with the semiconductor die.

13. The device of claim 10, wherein the recess is formed asymmetrical with respect to at least one of two orthogonal axes that each bisect the surface of the semiconductor die.

14. The device of claim 10, further comprising a metal layer formed on the surface of the semiconductor die to cover the embedded heat sink and at least a portion of the surface of the semiconductor die.

15. The device of claim 10, wherein the recess is formed symmetrical with respect to two orthogonal axes that each bisect the surface of the semiconductor die.

16. The device of claim 15, wherein an area of an exposed surface of the embedded heat sink is greater than an area than a remaining portion of the surface of the semiconductor die.

17. The device of claim 10, wherein the surface of the semiconductor die is a first surface, wherein the device further comprises electrical contacts formed on a second surface of the semiconductor die opposite the first surface.

18. The device of claim 17, wherein the device is one of a flip-chip chip-scale package (FCCSP) or a flip-chip ball-grid array (FCBGA).

19. A method for fabricating a circuit device, the method comprising:
forming electrical contacts on a first surface of a semiconductor die, the semiconductor die comprising a second surface opposite the first surface;
removing a portion of semiconductor material from the second surface of the semiconductor die to form a recess with respect to the second surface, the recess comprising at least one interior surface;
providing a metallization layer on the semiconductor material of the at least one interior surface of the recess; and
providing a metal material onto the metallization layer in the recess to at least partially fill the recess with the metal material to form an embedded heat sink in the semiconductor die.

20. The method of claim 19, wherein removing the portion of the semiconductor material comprises removing the portion of the semiconductor material that circumscribes a predetermined hot spot associated with the semiconductor die.

21. The method of claim 19, wherein removing the portion of the semiconductor material comprises removing the portion of the semiconductor material that is asymmetrical with respect to at least one of two orthogonal axes that each bisect the first surface of the semiconductor die.

22. The method of claim 19, further comprising providing a metal layer onto the first surface of the semiconductor die to cover the embedded heat sink and at least a portion of the first surface of the semiconductor die.

23. The method of claim 19, wherein removing the portion of the semiconductor material comprises removing the portion of the semiconductor material that is symmetrical with respect to two orthogonal axes that each bisect the first surface of the semiconductor die.

24. The method of claim 23, wherein removing the portion of the semiconductor material comprises removing the portion of the semiconductor material such that an area of an exposed surface of the embedded heat sink is greater than an area than a remaining portion of the first surface of the semiconductor die.
